(19) United States
(12) Patent Application Publication
(10) Pub. No.: US 2017/0103888 A1
(43) Pub. Date: Apr. 13, 2017

(54) AMINE CATALYSTS FOR LOW TEMPERATURE ALD/CVD SiO2 DEPOSITION USING HEXACHLORODISILANE/H2O

(71) Applicant: Entegris, Inc., Billerica, MA (US)

(72) Inventors: Dingkai Guo, Danbury, CT (US); Bryan C. Hendrix, Danbury, CT (US); Yuqi Li, Danbury, CT (US); Susan V. DiMeo, New City, NY (US); Weimin Li, New Milford, CT (US); William Hunks, Danbury, CT (US)

(21) Appl. No.: 15/292,760

(22) Filed: Oct. 13, 2016

Related U.S. Application Data
(60) Provisional application No. 62/240,588, filed on Oct. 13, 2015.

(51) Int. Cl. H01L 21/02; C23C 16/455; C23C 16/40

(52) U.S. Cl. CPC H01L 21/02211; C23C 16/402; C23C 16/45525; H01L 21/02164; H01L 21/0228

(57) ABSTRACT

A precursor composition is described, useful for low temperature (<150° C.) vapor deposition of silicon dioxide. The precursor composition includes hexachlorodisilane, water, and nitrogenous catalyst including an amide compound selected from the group consisting of N-ethylacetamide and N,N-dimethylformamide. Compositions and processes for forming silicon dioxide at a low temperature with alternative chemistries are also described, e.g., a precursor composition of chloroaminosilane and water, or a precursor composition of chlorosilane and ethanolamine, which may be utilized in pulsed chemical vapor deposition or atomic layer deposition processes.

### FIELD

The present disclosure relates to deposition of silicon, and more specifically to deposition of silicon-containing films such as silicon dioxide (SiO₂) at low temperature, such as temperature below 150° C., and to processes utilizing advantageous reagents and techniques for such deposition.

### DESCRIPTION OF THE RELATED ART

Hexachlorodisilane (HCDS) is widely used as a precursor for vapor deposition of silicon, e.g., for forming silicon dioxide and silicon nitride films via chemical vapor deposition (CVD) and atomic layer deposition (ALD), in the manufacture of semiconductor products, flat-panel displays, and solar panels, and in other applications in which very low temperature silicon oxide deposition is useful.

A conventional technique for forming silicon dioxide spacers for lithography in the aforementioned applications utilizes a precursor composition of HCDS, water, and pyridine to form a silicon dioxide film at temperatures below 150° C. by a vapor deposition process such as ALD or pulsed CVD. HCDS, while an effective silicon precursor, has associated handling and safety issues that require its careful use, being corrosive and producing flammable reaction products in reaction with water. In addition, the precursor composition of HCDS, water, and pyridine has associated risks attributable to pyridine, which although it is a highly effective catalyst for silicon oxide film formation when HCDS is utilized as a silicon precursor, has been identified as posing a risk of female sterility in sustained exposure to such chemical.

Accordingly, it would be advantageous to provide silicon precursors having improved handling and safety characteristics, as an alternative to the use of HCDS, as well as to provide alternative catalysts to pyridine for use with HCDS in instances where HCDS is a preferred silicon precursor for forming silicon oxide films.

### SUMMARY

The present disclosure relates to deposition of silicon, and more specifically to deposition of silicon-containing films such as silicon dioxide (SiO₂) at low temperature, e.g., below 150° C., and reagents and techniques for such deposition.

In one aspect, the disclosure relates to a precursor composition for low temperature (<150° C.) vapor deposition of silicon dioxide, said precursor composition comprising hexachlorodisilane, water, and nitrogenous catalyst comprising an amide compound selected from the group consisting of N-ethylacetamide and N,N-dimethylformamide.

In another aspect, the disclosure relates to a vapor deposition process for low temperature (<150° C.) deposition on a substrate of silicon dioxide, said process comprising volatilization of a precursor composition to form precursor vapor, and contacting the precursor vapor with a substrate to deposit silicon dioxide thereon, wherein the precursor composition comprises hexachlorodisilane, water, and nitrogenous catalyst comprising an amide compound selected from the group consisting of N-ethylacetamide and N,N-dimethylformamide.

In a further aspect, the disclosure relates to a method of manufacturing a product selected from the group consisting of semiconductor products, flat-panel displays, and solar panels, such method comprising the vapor deposition process of the present disclosure, as variously described herein.

A further aspect of the disclosure relates to a precursor composition for low temperature (<150° C.) vapor deposition of silicon dioxide, such precursor composition comprising chloroaminosilane and water.

A still further aspect of the disclosure relates to a method of forming a silicon dioxide film on a substrate, comprising contacting the substrate with chloroaminosilane and water, in alternating sequence.

In another aspect, the disclosure relates to a precursor composition for low temperature (<150° C.) vapor deposition of silicon dioxide, such precursor composition comprising chlorosilane and ethanolamine.

The disclosure in a further aspect relates to a method of forming a silicon dioxide film on a substrate, comprising contacting the substrate with chlorosilane and ethanolamine, in alternating sequence.

Other aspects, features and embodiments of the disclosure will be more fully apparent from the ensuing description and appended claims.

### BRIEF DESCRIPTION OF THE DRAWINGS

FIG. 1 is a schematic representation of a process system that may usefully be employed for atomic layer deposition of silicon dioxide films in accordance with the present disclosure, in various embodiments thereof.

FIG. 2 is a cycle diagram for deposition of a silicon dioxide film on a substrate, in a cycle including silicon precursor dosing, amine dosing, purging, water dosing, and purging.

FIG. 3 is a cycle diagram for deposition of a silicon dioxide film on a substrate, in a cycle including silicon precursor and amine dosing, post-dosing purging, water and amine dosing, and post-dosing purging.

FIG. 4 is a graph of deposition rate, in Angstroms/cycle, as a function of temperature, in ° C., for an ALD process utilizing an HCDS/water/nitrogenous catalyst precursor composition, wherein pyridine, NEA, and DMF were used in different runs of the deposition process.

FIG. 5 is a scanning electron microscope photomicrograph of a deposited SiO₂ film on a step coverage substrate, as formed using an N-Ethyl-Acetamide (NEA)-based precursor composition, showing that greater than 80% step coverage was achieved.

FIG. 6 is a scanning electron microscope photomicrograph of a deposited SiO₂ film on a step coverage substrate, as formed using a dimethylformamide-based precursor composition, showing that 100% step coverage was achieved.

FIG. 7 is a graph of etched thickness, in Angstroms, as a function of etching time, in seconds, for each of a thermal oxide film (♦), an NEA 50° C. film (X), and a pyridine 50° C. film (▪), showing that films formed from pyridine or NEA have similar etch rates.

### DETAILED DESCRIPTION

The present disclosure relates to deposition of silicon-containing films at low temperature, and to silicon precursors and catalysts, and processes, for such deposition.

As used herein and in the appended claims, the singular forms “a”, “and”, and “the” include plural referents unless the context clearly dictates otherwise.

The disclosure, as variously set out herein in respect of features, aspects and embodiments thereof, may in particular implementations be constituted as comprising, consisting, or consisting essentially of, some or all of such features, aspects and embodiments, as well as elements and components thereof being aggregated to constitute various further implementations of the disclosure. The disclosure correspondingly contemplates such features, aspects and embodiments, or a selected one or ones thereof, in various permutations and combinations, as being within the scope of the present disclosure.

As used herein, the term “film” refers to a layer of deposited material having a thickness below 1000 micrometers, e.g., from such value down to atomic monolayer thickness values. In various embodiments, film thicknesses of deposited material layers in the practice of the invention may for example be below 100, 10, or 1 micrometers, or in various thin film regimes below 200, 100, or 50 nanometers, depending on the specific application involved. As used herein, the term “thin film” means a layer of a material having a thickness below 1 micrometer.

In one aspect, the disclosure relates to a precursor composition for low temperature (<150° C.) vapor deposition of silicon dioxide, said precursor composition comprising hexachlorodisilane, water, and nitrogenous catalyst comprising an amide compound selected from the group consisting of N-ethylacetamide and N,N-dimethylformamide.

In such precursor composition, the nitrogenous catalyst may comprise N-ethylacetamide, or alternatively the nitrogenous catalyst may comprise N,N-dimethylformamide.

A further aspect of the disclosure relates to a vapor deposition process for low temperature (<150° C.) deposition on a substrate of silicon dioxide, said process comprising volatilization of a precursor composition to form precursor vapor, and contacting the precursor vapor with a substrate to deposit silicon dioxide thereon, wherein the precursor composition comprises hexachlorodisilane, water, and nitrogenous catalyst comprising an amide compound selected from the group consisting of N-ethylacetamide and N,N-dimethylformamide.

In such vapor deposition process, the nitrogenous catalyst may comprise N-ethylacetamide, or alternatively the nitrogenous catalyst may comprise N,N-dimethylformamide.

Such vapor deposition process may be carried out at low temperature (<150° C.), e.g., at temperature in a range of from 50 to 70° C.

The vapor deposition process of the present disclosure, as variously described above, may be employed to deposit silicon dioxide as a spacer for lithography, e.g., in manufacture of semiconductor products, flat-panel displays, solar panels, or other products, or in other applications in which very low temperature silicon oxide deposition is useful. The vapor deposition process may comprise a pulsed chemical vapor deposition process, or alternatively, an atomic layer deposition process.

The disclosure relates in a further aspect to a method of manufacturing a product selected from the group consisting of semiconductor products, flat-panel displays, and solar panels, such method comprising the vapor deposition process of the present disclosure, as variously described herein.

Another aspect of the disclosure relates to a precursor composition for low temperature (<150° C.) vapor deposition of silicon dioxide, such precursor composition comprising chloroaminosilane and water.

Yet another aspect of the disclosure relates to a method of forming a silicon dioxide film on a substrate, comprising contacting the substrate with chloroaminosilane and water, in alternating sequence. In various embodiments, the alternating sequence may be repeated until a desired silicon dioxide film thickness is achieved. The method in other embodiments may comprise purging of a reaction zone containing the substrate after contacting the substrate with chloroaminosilane and after contacting the substrate with water. The purging may for example be carried out with an inert gas such as argon. The method itself may comprise pulsed chemical vapor deposition or atomic layer deposition.

A further aspect of the disclosure relates to a precursor composition for low temperature (<150° C.) vapor deposition of silicon dioxide, such precursor composition comprising chlorosilane and ethanolamine.

In another aspect, the disclosure relates to a method of forming a silicon dioxide film on a substrate, comprising contacting the substrate with chlorosilane and ethanolamine, in alternating sequence. In various embodiments of such method, the alternating sequences repeated until a desired silicon dioxide film thickness is achieved. In other embodiments, the method may comprise purging of a reaction zone containing the substrate after contacting the substrate with chlorosilane and after contacting the substrate with ethanolamine. Such purging may be carried out with an inert gas, such as argon. The method itself may comprise pulsed chemical vapor deposition or atomic layer deposition.

The disclosure thus provides ALD formation of silicon dioxide films at low temperatures below 150° C., e.g., for applications such as forming spacers for lithography in the manufacture of products such as semiconductor products, flat-panel displays, and solar panels, or in other applications in which very low temperature silicon oxide deposition is useful.

The nitrogenous catalysts of the present disclosure have reduced health and/or flammability risks associated therewith, when used with HCDS for deposition of silicon dioxide films. As indicated, such nitrogenous catalysts include ammonia, 4-piperidinol, 4-methyl pyridine, N-ethyl acetamide (NEA), and N,N-dimethylformamide (DMF).

Set out below in Table 1 is a listing of these nitrogenous catalysts, along with pyridine for reference, with an identification of the volatility characteristics of such nitrogenous catalysts, their health and flammability characteristics (using the 4 point NFPA scale with highest value indicating highest risk), and the T50 characteristics of their hydrochloride salts. The T50 value is the temperature at which 50% of the hydrochloride salt is volatilized in a thermogravimetric measurement in flowing argon at ambient pressure and a 10° C./minute temperature ramp.

TABLE 1

| | | Amine Volatility | |
|---|---|---|---|
| | | MP = melting point | HCl Salt |
| Amine Name | Toxicity | BP = boiling point | T50 |
| Pyridine | Health 3 | MP −42° C. | 161.5° C. |
| | Flammability 3 | BP 115° C. | |
| Ammonia | Health 3 | MP −77.73° C. | 226.6° C. |
| | Flammability 1 | BP −33.34° C. | |
| 4-Piperidinol | Health 2 | BP 108° C. | 300.9° C. |
| | Flammability 1 | | |
| 4-Methyl Pyridine | Health 2 | MP 2.4° C. | 174.0° C. |
| | Flammability 2 | BP 145° C. | |
| N-Ethyl-Acetamide | Health 1 | BP 90° C. | 147.8° C. |
| (NEA) | Flammability 1 | T50 @135° C. | |
| N,N-Dimethyl- | Health 2 | MP −60° C. | 96.9° C. |
| formamide (DMF) | Flammability 2 | BP 152° C. | |
| | | T50 <81° C. | |

It therefore is seen from Table 1 that each of the listed alternative nitrogenous catalysts has various advantages over pyridine per se, and that NEA and DMF

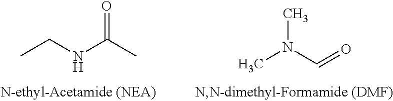

are highly suitable for use in HCDS/water/nitrogenous catalyst precursor compositions for low temperature (<150° C.) deposition of silicon dioxide, since they both show reduced hazards and high volatility (low T50).

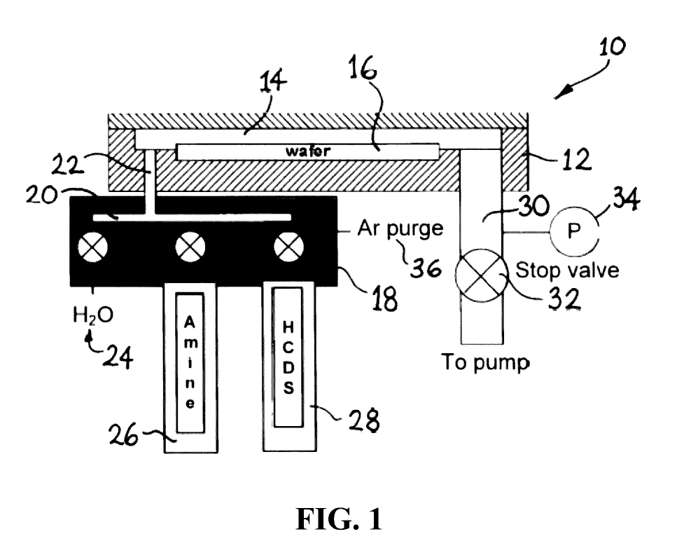

FIG. 1 is a schematic representation of an ALD process system 10 comprising a cross-flow vapor deposition chamber 12 defining an interior volume 14 in which a wafer 16 is mounted for vapor contacting. The ALD process system includes a valved manifold 18 including manifold passage 20 communicating with vapor feed passage 22 configured to flow vapor phase components to the interior volume in the vapor deposition chamber.

The valve manifold is coupled with sources 24, 26, and 28 of water, amine catalyst, and silicon precursor, respectively. Each of such sources is coupled with flow circuitry passages in the valved manifold, so that each of the flows of water, amine catalyst, and silicon precursor from the respective sources may be independently controlled.

The interior volume 14 of the vapor deposition chamber 12 is coupled with an effluent discharge conduit 30 containing stop valve 32. The discharge conduit 30 is coupled at a discharge end thereof with a pump (not shown in FIG. 1), and pressure of the effluent gas discharged from the interior volume of the vapor deposition chamber is monitored by pressure sensor 34, which may constitute a pressure gauge of conventional type.

A source 36 of argon is provided for purging all of the precursor ALD valves in the valved manifold 18 and flowing such purge gas continually through the interior volume of the vapor deposition chamber.

A vapor deposition apparatus of a type as shown in FIG. 1 was employed to evaluate amine catalysts, using HCDS as a silane precursor, and with water as a co-reactant, in an ALD process for deposition of SiO₂ on the wafer substrate.

In such evaluation using the ALD apparatus, the gas phase precursors were dosed into the vapor deposition chamber 12 by vapor draw. Since there was no pressure control for the chamber, transient pressure burst was observed in the pressure gauge 34 when dosing the precursors.

A steady state flow of argon purge gas was flowed through the valved manifold for purging of precursor valves therein and was continuously flowed through the vapor deposition chamber. The chamber had a base pressure of 300 millitorr at a purge gas flow of 20 standard cubic centimeters of argon per minute (sccm Ar). The sample substrate used in the evaluation was a 200 mm diameter silicon Si(100) wafer.

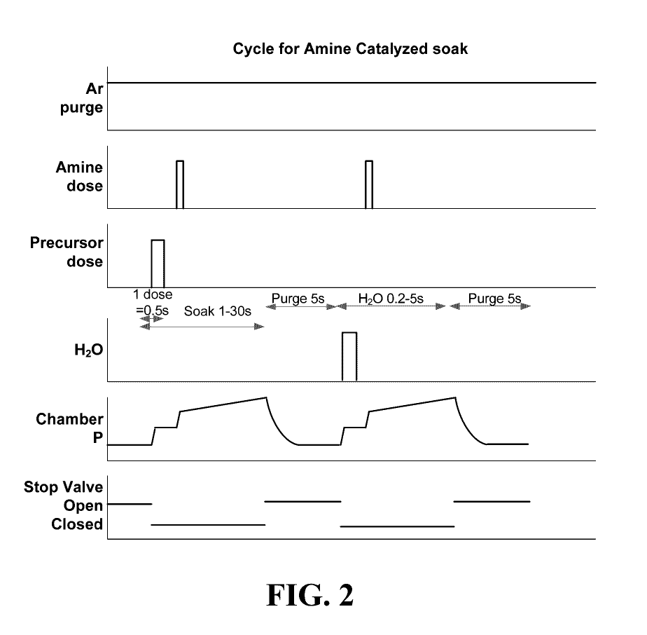

SiO₂ deposition experiments were performed using a reaction sequence as depicted in the cycle diagram of FIG. 2.

FIG. 2 is a cycle diagram for deposition of a silicon dioxide film on a substrate, in a cycle including silicon precursor dosing, amine dosing, purging, water dosing, and purging. The stop valve was closed at the beginning of precursor dosing. Hexachlorodisilane was first pulsed into the deposition chamber by opening the HCDS ALD valve in the valved manifold for 0.5 seconds. The amine catalyst was then introduced and mixed with HCDS accumulated in the chamber. The stop valve then was open to purge away unreacted precursors, while retaining the baseline pressure, and then closed. H₂O was then dosed into the chamber followed by the amine catalyst. The stop valve then was reopened to purge away the unreacted precursors and remove amine salt from the SiO₂ surface and the deposition chamber walls.

The resulting sample was characterized by spectroscopic ellipsometer (J.A. Woolam Co.) for film thickness and reflective index.

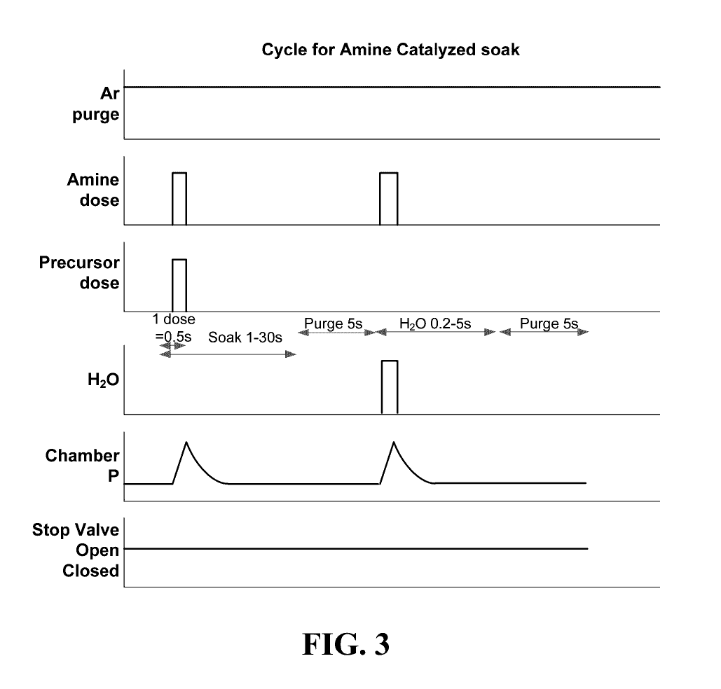

FIG. 3 shows an alternative pulsing sequence that could be conducted with a process system of a type as described above. In this alternative sequence, a silicon dioxide film is deposited on a substrate, in a cycle including silicon precursor and amine dosing, post-dosing purging, water and amine dosing, and post-dosing purging. In this alternative sequence, with the stop valve open during the reaction, HCDS and amine catalyst were co-flowed to the deposition chamber at a constant pressure, followed by purge, and then H₂O and amine catalyst were co-flowed to the deposition chamber, followed by purge, before repeating the cycle sequence.

The sample resulting from the alternative sequence was characterized by spectroscopic ellipsometer (J.A. Woolam Co.) for film thickness and reflective index.

The NEA and DMF amine catalysts were comparatively tested against pyridine in successive runs of an ALD process utilizing an HCDS/amine/H₂O process for depositing silicon dioxide, and deposition rate was determined as a function of temperature in such successive runs.

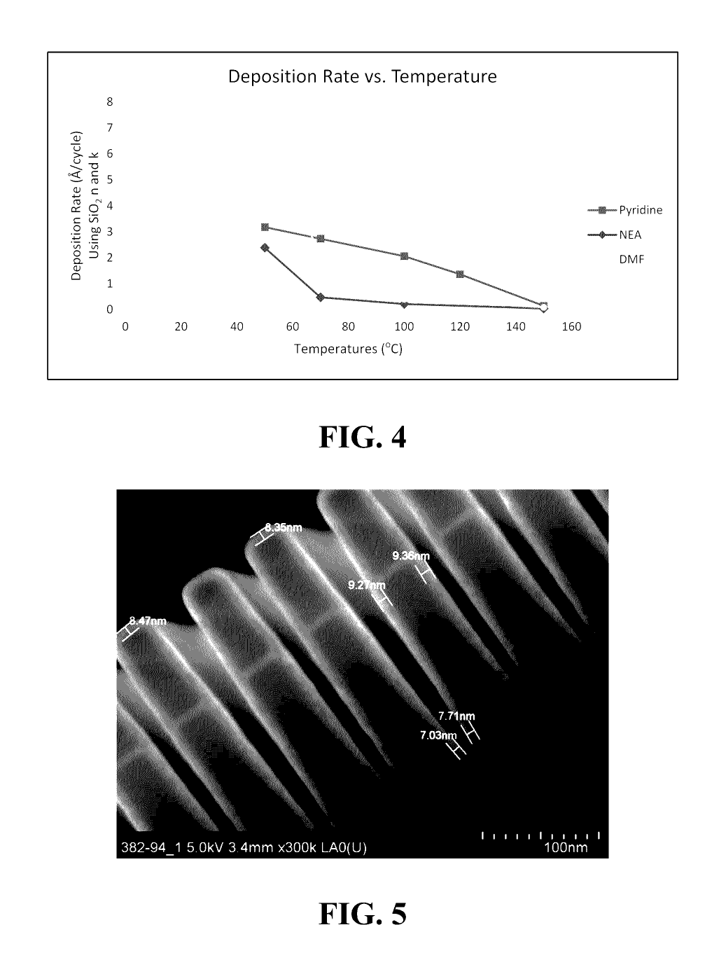

FIG. 4 is a graph of deposition rate, in Angstroms/cycle, as a function of temperature, in ° C., for these ALD process runs, utilizing the HCDS/water/nitrogenous catalyst precursor composition, wherein pyridine, NEA, and DMF were used in the successive runs of the deposition process. Different amine doses were tested for the process. It was determined that both HCDS and H₂O do not saturate with longer dose time. The data show that use of DMF at temperature of 50° C. to 60° C. produced significantly higher deposition rate of silicon dioxide than when using either pyridine or NEA.

Additional data based on spectroscopic ellipsometry (SE) measurements are set out in Table 2 below.

TABLE 2

| Wafer | n @ | Thickness, | Ångströms/ |
|---|---|---|---|
| Temperature | 636 nm | Ångströms | cycle |
| 50° C. Pyridine | 1.513 | 286 | 2.86 |
| 50° C. NEA | 1.525 | 309 | 2.06 |
| 50° C. DMF | 1.499 | 222 | 4.44 |
| 70° C. DMF | 1.5 | 216 | 1.66 |
| SiO₂ | 1.457 | n/a | n/a |

NEA-based precursor compositions were assessed for step coverage results at 50° C. Room temperature HCDS and NEA deposited at 50° C. were utilized, for 45 cycles involving the following cycle sequence: HCDS 0.5 second-NEA 10 dose/soak 1 second, H₂O 2 seconds-NEA 10 dose/soak 1 second. FIG. 5 is a photomicrograph of the deposited film on the step coverage substrate, showing that greater than 80% step coverage was achieved, as determined by scanning electron microscope characterization.

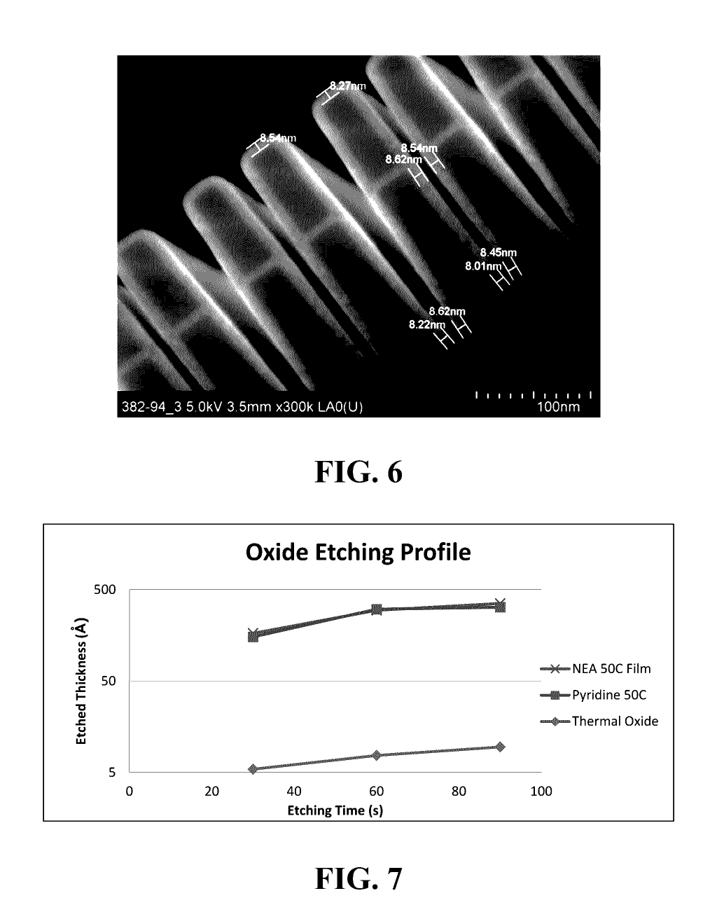

DFM-based precursor compositions were next assessed for step coverage results at 70° C. Room temperature HCDS and DMF deposited at 70° C. were utilized, for 50 cycles involving the following cycle sequence: HCDS 0.5 second-DMF 2 seconds/soak 1 second, H₂O 2 seconds-DMF 2 seconds/soak 1 second. FIG. 6 is a photomicrograph of the deposited film on the step coverage substrate, showing that 100% step coverage was achieved, as determined by scanning electron microscope characterization.

HCDS/pyridine or NEA film oxide etching was assessed for coupons from 7 wafers, utilizing HCDS/pyridine or NEA-deposited 50° C. film. In this assessment, a thermal oxide film 1000 Å thick was considered for comparison purposes. The etching solutions were 400:1 hydrogen fluoride solutions. Etching times were 30 seconds, 60 seconds, and 90 seconds, with 3 repetitions. The thermal oxide film was utilized as a thickness measurement recipe. Data from the etching assessment are set out in Table 3 below, and graphically shown in FIG. 7.

TABLE 3

| | Etch Rates |
|---|---|
| HCDS Films | (Ångströms/minute) |
| Thermal Oxide | 7 |
| NEA 50° C. | 300 |
| Pyridine 50° C. | 300 |

FIG. 7 is a graph of etched thickness, in Angstroms, as a function of etching time, in seconds, for each of a thermal oxide film (♦), an NEA 50° C. film (X), and a pyridine 50° C. film (▪). The data show that films from 50° C. pyridine or NEA have similar etch rates.

Another aspect of the present disclosure relates to the use of alternative precursor compositions for forming silicon dioxide films by chemical vapor deposition or atomic layer deposition.

In a first compositional aspect, the precursor composition comprises chloroaminosilane and H₂O. In the use of such composition in a pulsed CVD or an ALD process, the chloroaminosilane is introduced to the vapor deposition chamber in a first step, followed by purging, followed by water vapor introduction, followed by purging, with the cycle being repeated for as many cycle repetitions as may be necessary or desirable in a given application of such methodology.

In a second compositional aspect, the precursor composition comprises chlorosilane and ethanolamine. In the use of such composition in a pulsed CVD or an ALD process, the chlorosilane is introduced to the vapor deposition chamber in a first step, followed by purging, followed by ethanolamine introduction, followed by purging, with the cycle being repeated as appropriate, for as many cycle repetitions as may be needed to provide a silicon dioxide film of desired character.

The above-described alternative precursor compositions enable low temperature (<150° C.) silicon dioxide deposition, in an ozone-free, plasma-free, and pyridine-free ALD/CVD process.

While the disclosure has been set forth herein in reference to specific aspects, features and illustrative embodiments, it will be appreciated that the utility of the disclosure is not thus limited, but rather extends to and encompasses numerous other variations, modifications and alternative embodiments, as will suggest themselves to those of ordinary skill in the field of the present disclosure, based on the description herein. Correspondingly, the disclosure as hereinafter claimed is intended to be broadly construed and interpreted, as including all such variations, modifications and alternative embodiments, within its spirit and scope.

1. A precursor composition for low temperature (<150° C.) vapor deposition of silicon dioxide, said precursor composition comprising hexachlorodisilane, water, and nitrogenous catalyst comprising an amide compound selected from the group consisting of N-ethylacetamide and N,N-dimethylformamide.

2. The precursor composition of claim 1, wherein the nitrogenous catalyst comprises N-ethylacetamide.

3. The precursor composition of claim 1, wherein the nitrogenous catalyst comprises N,N-dimethylformamide.

4. A vapor deposition process for low temperature (<150° C.) deposition on a substrate of silicon dioxide, said process comprising volatilization of a precursor composition to form precursor vapor, and contacting the precursor vapor with a substrate to deposit silicon dioxide thereon, wherein the precursor composition comprises hexachlorodisilane, water, and nitrogenous catalyst comprising an amide compound selected from the group consisting of N-ethylacetamide and N,N-dimethylformamide.

5. The vapor deposition process of claim 4, wherein the nitrogenous catalyst comprises N-ethylacetamide.

6. The vapor deposition process of claim 4, wherein the nitrogenous catalyst comprises N,N-dimethylformamide.

7. The vapor deposition process of claim 4, wherein said contacting is carried out at temperature in a range of from 50 to 70° C.

8. The vapor deposition process of claim 4, wherein the deposited silicon dioxide forms a spacer for lithography.

9. The vapor deposition process of claim 4, comprising a pulsed chemical vapor deposition process.

10. The vapor deposition process of claim 4, comprising an atomic layer deposition process.

11. A method of manufacturing a product selected from the group consisting of semiconductor products, flat-panel displays, and solar panels, said method comprising the vapor deposition process according to claim 4.

12-27. (canceled)
